(19) United States
(12) Patent Application Publication
(10) Pub. No.: US 2009/0106638 A1
(43) Pub. Date: Apr. 23, 2009

(54) CALCULATION PROCESSING DEVICE FOR PERFORMING HIGH-SPEED CALCULATION

(75) Inventors: Wakako NAKASE, Tokyo (JP); Isao TAKAMI, Tokyo (JP)

Correspondence Address: Studebaker & Brackett PC, 1890 Preston White Drive, Suite 105, Reston, VA, 20191, US

(73) Assignee: OKI ELECTRIC INDUSTRY CO., LTD., Tokyo (JP)

(21) Appl. No.: 12/239,851

(22) Filed: Sep. 29, 2008

(30) Foreign Application Priority Data
Oct. 17, 2007 (JP) 2007-269944
Oct. 26, 2007 (JP) 2007-279513

(51) Int. Cl. G06F 15/76; H03M 13/09; G06F 9/02; G06F 11/10

(52) U.S. Cl. 714/807; 712/36; 712/E09.002; 714/E11.032

(57) ABSTRACT

In a calculation processing device for calculating inputted data to output the result of the calculation, a number-of-calculation generator generates the numbers of parallel and serial calculations based on the data length of the received data. When a calculation enable generator applies a parallel enabling signal or a serial enabling signal to an input controller in order to control the numbers of these calculations, the received data is inputted to a calculation processor in parallel during an input period of the parallel enabling signal, and is inputted to the calculation processor in serial during an input period of the serial enabling signal. The calculation processor performs parallel and serial processes for the inputted data to output the results of the processes on an output.

### BACKGROUND OF THE INVENTION

1. Field of the Invention

The present invention relates to a calculation processing device for performing a high-speed calculation, and more particularly to a calculation processing device for performing a high-speed calculation in error detection such as a CRC (Cyclic Redundancy Check) algorithm.

2. Description of the Background Art

Algorithms for detecting data errors are exemplified by CRC. The process of detecting errors through the CRC algorithm, when transmitting and receiving data, calculates a bit string for inspection through a generator polynomial to transmit data obtained by adding the resulting bit string to transmitted information bits on a transmitter side, and to divide on a receiver side the received data by the same generator polynomial as the transmitter side to obtain the residue, thereby detecting the error.

In the configuration of a 16-bit CRC calculation process, using the generator polynomial of G(x)=X¹⁶+X¹²+X⁵+1, generally according to the ITU-T (International Telecommunications Union-Telecommunications Standardization Sector) recommendation, received data can be inputted to a residue calculation circuit of the generator polynomial G(x) in serial to thereby obtain the residue. After inputting all bits of the received data, a 16-bit value left in a shift register is equal to the residue to be divided by the generator polynomial G(x). Since the transmitter side adds CRC code bits to transmit data so that the residue is rendered to be zero, an error in the received data is detected when the shift register holds a value other than zero.

In the case of this configuration, since received data are inputted in serial, the same number of times of calculation as the bits of the received data is required. Generally, since a single calculation needs a single clock cycle, the same number of clock cycles as the bits of the received data is needed per calculation process. However, when a period of calculation processing time for this calculation process has to be shorter than that corresponding to the number of bits of the received data, this process needs a higher clock rate for its calculation process, or otherwise a parallel calculation circuit. A parallel calculation circuit is adapted to receive received data in parallel to thereby enable the plurality of received data to be calculated at the same time, which can reduce the number of calculations significantly.

Japanese Patent Laid-Open Publication No. 209880/1998 discloses a CRC calculator circuit that receives data on its data input terminals in parallel and outputs data in parallel.

In order to reduce a period of processing time for a CRC calculation, for example, the operational clock rate of a CRC calculation processing circuit can be increased to speed up the calculation process, or a parallel calculation process can be applied to speed up it. However, the operational clock rate increased a problem such as an increase in power consumption accordingly. Therefore, a parallel calculation process is necessary.

However, in the circuit configurations of conventional parallel calculation processes, the number of calculations has to be equal to a divisor of the number of all bits of the received data. Therefore, when receiving variable length data or data having its data length equal to a prime number, the parallel calculation process cannot be applied, which causes a problem that speeding up is impossible.

### SUMMARY OF THE INVENTION

It is therefore an object of the present invention to provide a calculation processing device capable of a high-speed calculation process without depending upon the data length of received data.

In accordance with the present invention, a calculation processing device for calculating inputted data to output the result of the calculation includes a parallel calculator for calculating the data in parallel, a serial calculator for calculating the data in serial, an input controller for converting the data to the parallel and serial formats, and a switching controller operative in response to the processed data length and the number of processes for enabling a calculation process of either one of the parallel and serial calculators to switch the parallel or serial calculator.

In an aspect of the present invention, the parallel and serial calculators may process a CRC calculation of the data. In addition, the instant device may be such that a period of processing time depends on the data length of data to be calculated by the parallel and serial calculators. Furthermore, the input controller may inversely output the converted data again, and the serial calculator may perform an inverse serial process.

In accordance with the present invention, the parallel and serial calculation processing functions can be switched in response to the inputted data length and the number of calculations to be used, thereby performing the CRC calculation process, which enables a high-speed calculation to be performed with any received data length by using the parallel calculation processing functions. This can perform the high-speed calculation by the parallel calculation process even when the received data are processed which have a data length that cannot be indivisible by the number of the parallels, for example, of a prime number, and that is not suitable for the parallel calculation process.

In addition, even when the number of bits for the calculation is not determined at the start time of the calculation, it can start with the provisionally-determined number of the parallel calculations. Thereafter, when the number of bits for the calculation is fixed, the extra calculation is cancelled by the inverse serial calculation process, or the parallel calculations are further added to compensate for the excess or deficiency, whereby the number of bits to be calculated can be adjusted.

### BRIEF DESCRIPTION OF THE DRAWINGS

The objects and features of the present invention will become more apparent from consideration of the following detailed description taken in conjunction with the accompanying drawings in which:

FIG. 1 is a schematic block diagram showing a preferred embodiment of a CRC calculation circuit in accordance with the present invention;

FIG. 2 shows an illustrative configuration of received data;

FIG. 3 shows received data structure useful for understanding the operation of parallel and serial processes;

FIG. 4 shows an illustrative configuration of a calculation processor in a schematic circuit diagram;

FIG. 5 shows a connecting path in the operation of a serial calculation in a schematic circuit diagram;

FIG. 6 shows a connecting path in the operation of a parallel calculation in a schematic circuit diagram;

FIG. 7 is a schematic block diagram, like FIG. 1, showing an alternative embodiment of the CRC calculation circuit in accordance with the present invention;

FIG. 8 shows, like FIG. 2, an illustrative configuration of received data in the alternative embodiment;

FIG. 9 shows in a schematic circuit diagram, like FIG. 4, an illustrative configuration of a calculation processor in the embodiment shown in FIG. 7; and

FIG. 10 shows, like FIG. 3, received data structure useful for understanding the operation of parallel and inverse serial processes.

### DESCRIPTION OF THE PREFERRED EMBODIMENTS

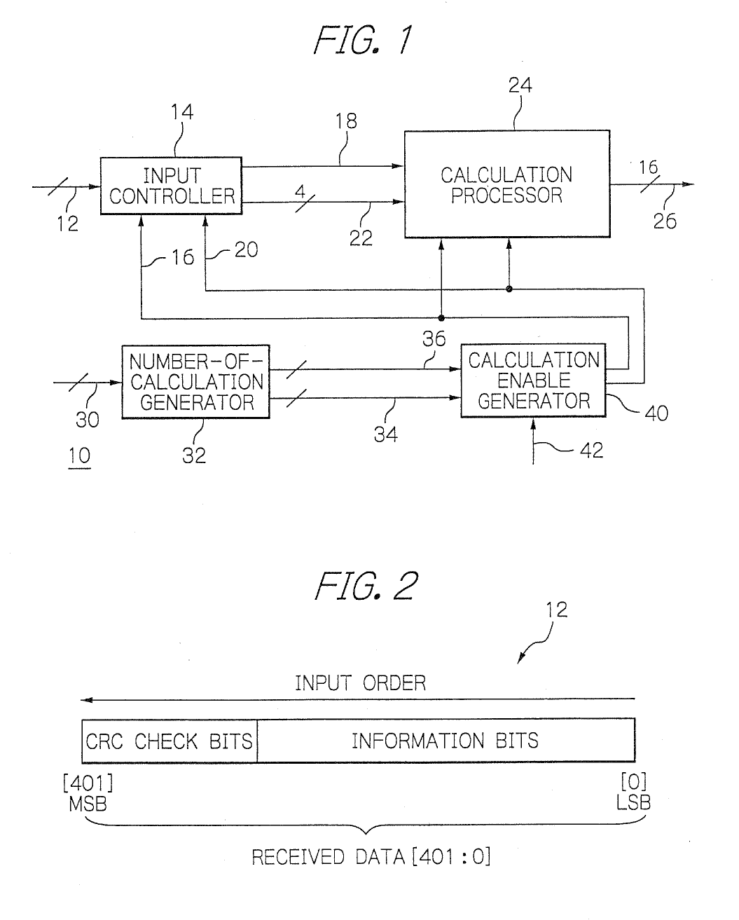

Well, reference will be made to accompanying drawings to describe in detail a calculation processing device in accordance with preferred embodiments of the present invention. With reference to FIG. 1, a preferred embodiment of the present invention is directed to a calculation processing device including a CRC (Cyclic Redundancy Check) calculation circuit 10. As shown in the figure, the CRC calculation circuit 10 is adapted to process 16-bit CRC according to the ITU-T recommendation, and has a function to calculate received data inputted on an input 12 in serial or parallel.

Particularly, the CRC calculation circuit 10 includes an input controller 14 for converting the received data 12 to serial or 4-bit parallel data 18 or 22 to output them. In the description, signals or data are designated with reference numerals of connections on which they are conveyed. The received data, as showing its illustrative configuration in FIG. 2, has a format such that information bits are stored in its LSB (Least Significant Bit) side, and CRC check bits are stored in its MSB (Most Significant Bit) side, the CRC calculation process being performed in the order of data from its LSB side to its MSB side. In the example thus shown, the length of the received data is 402 bit.

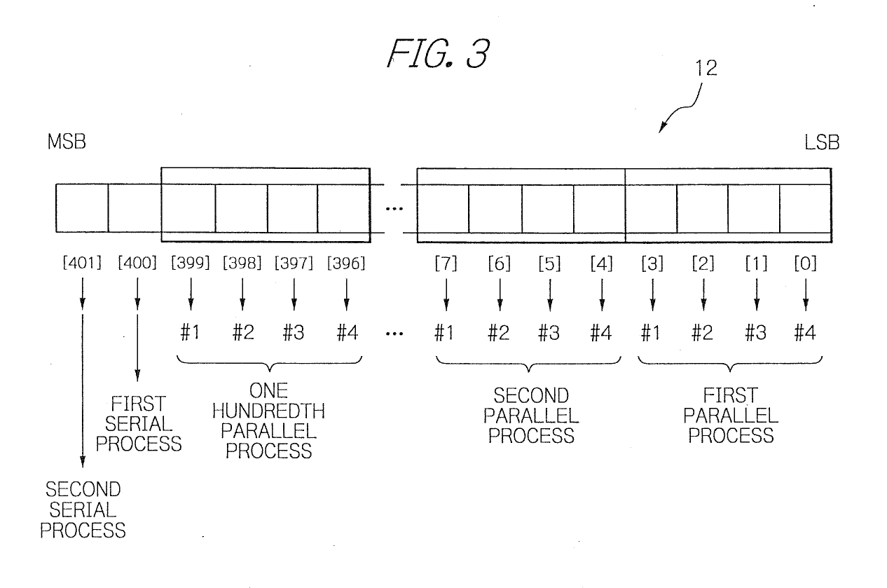

The input controller 14, when receiving a serial enabling signal over an input 16, converts received data 12 to a serial format to output the converted data from the LSB side on the output 18 a bit at a time, and when receiving a parallel enabling signal on an input 20, converts the received data 12 to a 4-bit parallel format to output the converted data to the output 22 four bits at a time. FIG. 3 shows how the input controller 14 outputs the data four bits at a time by way of example. The input controller 14 has its outputs 18 and 22 connected to a calculation processor 24.

The calculation processor 24 is adapted to calculate the CRC of the received data outputted from the input controller 14, and has two kinds of calculation processing functions, i.e. a serial calculation process and a parallel calculation process dealing with four bits at a time. The calculation processor 24 is controlled so as to process input data to the input 18 through a serial calculation when receiving the serial enabling signal 16, and to process input data to the input 22 through a parallel calculation when receiving the parallel enabling signal 20. The calculation processor 24 outputs a calculation result as output data of the CRC calculation circuit 10 to an output 26. As shown in FIG. 3, the calculation processor 24 in this embodiment, when receiving the received data shown in FIG. 2 four bits at a time, performs parallel processes one hundred times, and then performs serial processes two times, thereby processing all bits of the received data. The configuration of the calculation processor 24 will hereinafter be described in detail.

The CRC calculation circuit 10 further includes a number-of-calculation generator 32 for receiving information representing the bit length of the received data 12 on an input 30 to determine from the data length the numbers of serial and parallel calculations of the CRC calculation process. The number-of-calculation generator 32 divides the bit length of the received data 12 by the number of bits for a parallel process to output a resultant quotient on an output 34 as the number of parallel calculations and output a resultant residue as the number of serial calculations on an output 36. The CRC calculation circuit 10 has its outputs 34 and 36 connected to a calculation enable generator 40.

The calculation enable generator 40, when a calculation start signal 42 externally applied is in its “ON” state, i.e. enabled, generates a serial enabling signal 16 and a parallel enabling signal 20 based on the numbers of serial and parallel calculations applied by the number-of-calculation generator 32, respectively. The calculation enable generator 40 outputs the generated serial and parallel enabling signals 16 and 20 to the input controller 14 and the calculation processor 24.

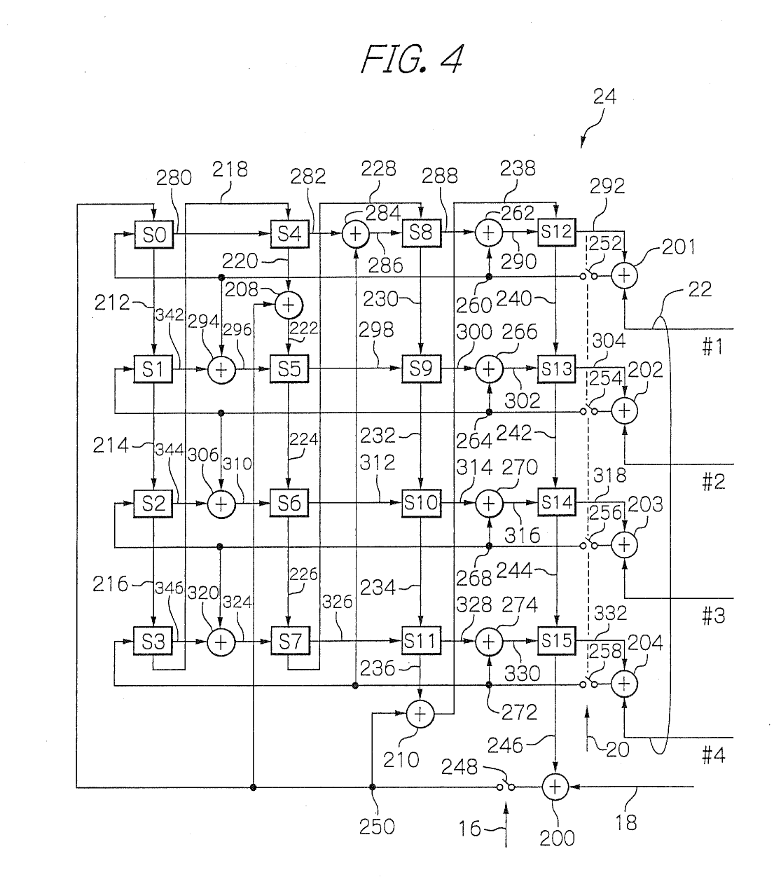

The illustrative configuration of the calculation processor 24 in detail is shown in FIG. 4. As shown in the figure, the calculation processor 24 has its serial input 18 connected to one input of an exclusive OR gate 200, and has its 4-bit parallel input 22 connected to one input of exclusive OR gates 201, 202, 203, and 204.

The exclusive OR gate 200 is connected to an output 246 of one S15 of shift registers S0 to S15, outputting the calculation result to an input of the shift register S0 and one input of each of exclusive OR gates 208 and 210 through a switch 248 over a connecting line 250. The shift register S0 has its output 212 connected to the shift register S1, which has its output 214 connected to the shift register S2, which has its output 216 connected to the shift register S3, which has its output 218 connected to the shift register S4. The shift register S4 has its output 220 connected to the other input of the exclusive OR gate 208, which further has its output 222 connected to the shift register S5.

The shift register S5 has its output 224 connected to the shift register S6, which has its output 226 connected to the shift register S7, which has its output 228 connected to the shift register S8, which has its output 230 connected to the shift register S9, which has its output 232 connected to the shift register S10, which has its output 234 connected to the shift register S11. The shift register S11 has its output 236 connected to the other input of the exclusive OR gate 210, which further has its output 238 connected to the shift register S12.

The shift register S12 has its output 240 connected to the shift register S13, which has its output 242 connected to the shift register S14, which has its output 244 connected to the shift register S15, which has its output 246 connected to the exclusive OR gates 200. Over the connecting path of the above-described shift registers S0 to S15, when the serial enabling signal 16 is its “ON” state, the serial calculation process is performed.

In addition, a parallel signal is inputted to the exclusive OR gates 201, 202, 203, and 204, which are connected to switches 252, 254, 256, and 258, respectively, which will be turned on together in response to the parallel enabling signal 20. When having the parallel enabling signal 20 inputted, the switch 252 connects an output of the exclusive OR gates 201 to the shift register S0 and one input of each of the exclusive OR gates 262 and 294 through a connecting line 260. Similarly, in response to the parallel enabling signal 120, the switch 254 connects an output of the exclusive OR gates 202 to the shift register S1 and one input of each of the exclusive OR gates 266 and 306 through a connecting line 264. Similarly, in response to the parallel enabling signal 20, the switch 256 connects an output of the exclusive OR gates 203 to the shift register S2 and one input of each of the exclusive OR gates 270, 320 through a connecting line 268. Similarly, in response to the parallel enabling signal 20, the switch 258 connects an output of the exclusive OR gates 204 to the shift register S3 and one input of each of the exclusive OR gates 274 and 284 through a connecting line 272.

The shift registers S0 to S3 hold data inputted on the connecting lines 260, 264, 268, and 272, and then output the data in order on outputs 280, 342, 344, and 346, respectively. The shift register S0 has its output 280 connected to the shift register S4, which has its output 282 connected to one input of the exclusive OR gate 284. The exclusive OR gate 284 has its other input connected to the connecting line 272. The exclusive OR gate 284 has its output 286 connected to the shift register S8, which has its output 288 connected to the other input of the exclusive OR gate 262, which has its output 290 connected to the shift register S12, which has its output 292 connected to the other input of the exclusive OR gate 201.

In addition, the shift register S1 has its output 342 connected to one input of the exclusive OR gate 294, which has its other input connected to the connecting line 260. The exclusive OR gate 294 has its output 296 connected to the shift register S5, which has its output 298 connected to the shift register S9. The shift register S9 has its output 300 connected to the other input of the exclusive OR gate 266, which has its output 302 connected to the shift register S13, which has its output 304 connected to the other input of the exclusive OR gate 202.

In addition, the shift register S2 has its output 344 connected to one input of the exclusive OR gate 306, which has its other input connected to the connecting line 264. The exclusive OR gate 306 has its output 310 connected to the shift register S6, which has its output 312 connected to the shift register S10. The shift register S10 has its output 314 connected to the other input of the exclusive OR gate 270, which has its output 316 connected to the shift register S14, which has its output 318 connected to the other input of the exclusive OR gate 203.

In addition, the shift register S3 has its output 346 connected to one input of the exclusive OR gate 320, which has its other input connected to the connecting line 268. The exclusive OR gate 320 has its output 324 connected to the shift register S7, which has its output 326 connected to the shift register S11. The shift register S11 has its output 328 connected to the other input of the exclusive OR gate 274, which has its output 330 connected to the shift register S15, which has its output 332 connected to the other input of the exclusive OR gate 204. Meanwhile, although not shown in FIG. 4 in order to prevent the figure from being complicated, each of the shift registers S0 to S15 has its output connected to the output 26 having 16 bits of the calculation processor 24 shown in FIG. 1.

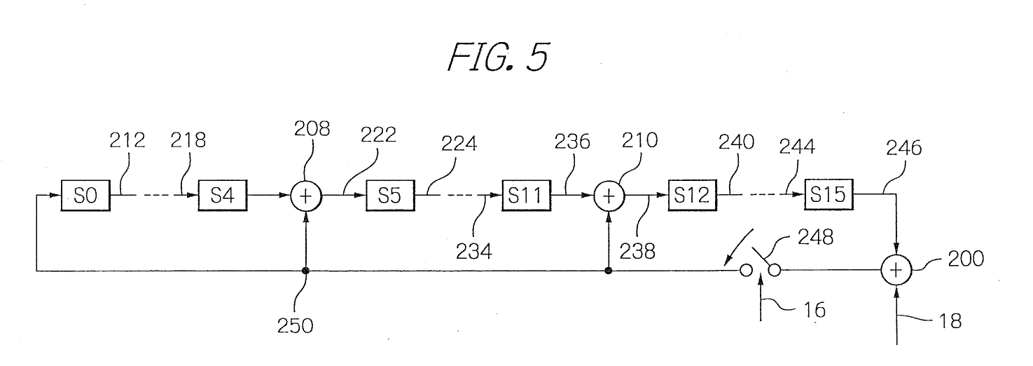

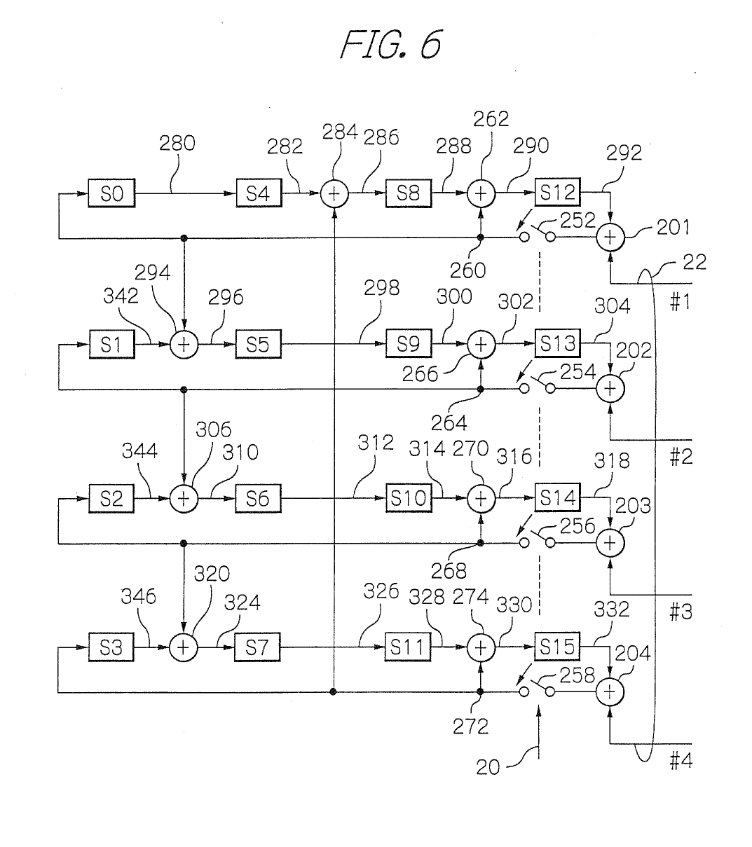

When the serial enabling signal 16 is in its “ON” state and the parallel enabling signal 20 is in its “OFF” state, the switch 248 is turned on to perform the serial calculation on the connecting path configured as shown in FIG. 5. When the serial enabling signal 16 is in its “OFF” state and the parallel enabling signal 20 is in its “ON” state, the switches 252, 254, 256, and 258 are turned on to perform the parallel calculation on the connecting path configured as shown in FIG. 6.

An operation of the CRC calculation circuit 10 in this embodiment will be described. For illustrative purposes, this embodiment has a received data length of 402 bits. First, the shift registers S0 to S15 in the calculation processor 24 initialize themselves to initial values matching a transmitter side.

The number-of-calculation generator 32 divides the received data length of 402 bits by four as the number of bits for a parallel calculation, thereby setting the number of times of the parallel calculations to the quotient of 100 and the number of times of the serial calculations to the residue of 2. The parallel and serial processes shown in FIG. 3 are determined in this way.

The 4-bit parallel calculations are performed one hundred times, of which the total is 400 bits. The serial calculations are performed two times, i.e. two bits. The total is 402 bits (400+2 bits), which performs the CRC calculation process for the received data of 402 bits.

The calculation enable generator 40, when receiving the calculation start signal 42 for enabling, outputs the parallel enabling signal 20 for enabling based on the result generated by the number-of-calculation generator 32 while the parallel calculation cycles are performed one hundred times. The input controller 14, while receiving the parallel enabling signal 20, outputs the received data four bits at a time on the output 22 in order from its LSB side.

The calculation processor 24 receives the parallel data 22 outputted from the input controller 14, and, while receiving the parallel enabling signal 20 from the calculation enable generator 40, performs the CRC parallel calculations.

Of the 4-bit parallel data inputted from the input controller 14 to the calculation processor 24, the LSB bit, the second bit from the LSB, the third bit from the LSB, and the MSB bit are inputted to bit positions #4, #3, #2, and #1 of the input 22, respectively, FIG. 3.

The calculation enable generator 40, once the parallel calculation cycles are finished being processed one hundred times, turns off the parallel enabling signal 20 and outputs the serial enabling signal 16 for enabling while the serial calculation cycles are processed two times.

The input controller 14, while receiving the serial enabling signal 16 for enabling, outputs the rest of the received data 12 on the output 18 a bit at a time in order from the LSB side. The calculation processor 24 receives the serial data 18 outputted from the input controller 14, and, while receiving the serial enabling signal 16 for enabling, performs the CRC serial calculations. The calculation enable generator 40, once the serial calculation cycles are finished being processed two times, turns off the output of the serial enabling signal 16.

The calculation processor 24 outputs remaining values held in the shift register S0 to S15 from the output 26. At this time, when the outputted values are not zero, the received data 12 is determined to be wrong.

As described above, in the illustrative embodiment, in response to the inputted data length and the number of calculations, the parallel and serial calculation processing functions are adapted to be switched to perform the CRC calculation process. Therefore, for any data length, the parallel calculation processing function can be used to perform a high-speed calculation. This can perform the high-speed calculation by the parallel calculation process even when the received data are processed which have the data length thereof that cannot be indivisible by the number of parallels, for example, of a prime number, and that is not suitable for the parallel calculation process.

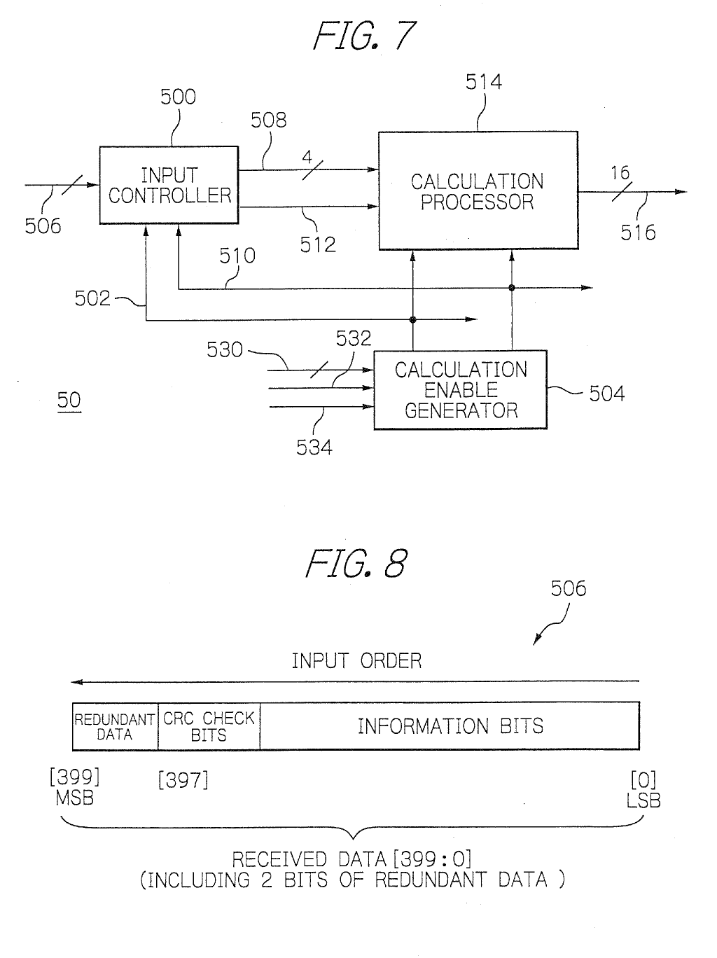

Next, a calculation processing device in accordance with an alternative embodiment of the present invention will be described. FIG. 7 shows a CRC calculation circuit 50 of the ITU-T 16 bit CRC. The CRC calculation circuit 50 in this embodiment has two functions to calculate the received data through 4-bit parallel and to inversely calculate the already-calculated data in serial.

Particularly, an input controller 500, when receiving a parallel enabling signal 502 for enabling from a calculation enable generator 504, outputs received data inputted on an input 506 from the LSB side to an output 508 four bits at a time in parallel. When the parallel enabling signal 502 is turned off and the calculation enable generator 504 supplies an inverse serial enabling signal 510 for enabling, the input controller 500 outputs data a bit at a time on an output 512 from the final, outputted data (MSB) in the already-outputted data. The received data in this embodiment, as showing its illustrative configuration in FIG. 8, has a format such that information bits are stored in its LSB side, subsequently CRC check bits are stored, and redundant data are stored in its MSB side, being processed through the CRC calculation from data in its LSB side. In the example thus shown, the length of the received data is 398 bits, to which two bits of the redundant data are added.

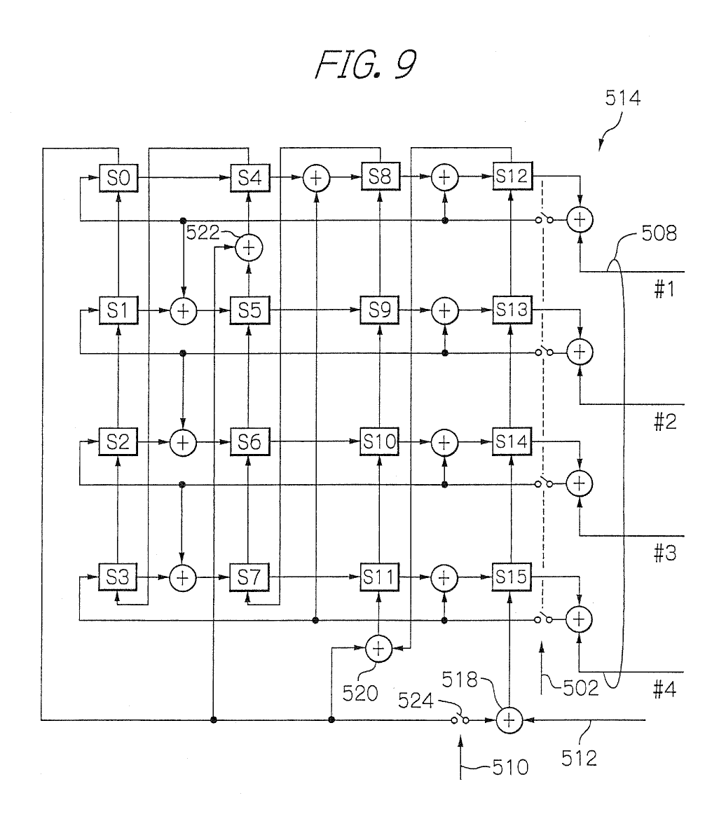

The input controller 500 has its outputs 508 and 512 connected to a calculation processor 514. The calculation processor 514 has functions to the CRC calculation process by a 4-bit parallel calculation process, and to inversely calculate the serial data. The calculation processor 514 includes 16-bit shift registers S0 to S15 and 15 exclusive OR (EXOR) gates, and is controlled by a parallel enabling signal 502 and an inverse serial enabling signal 510. The calculation processor 514 outputs results of the CRC calculation process and the inverse calculation process on an output 516. The illustrative configuration of the calculation processor 514 in detail is shown in FIG. 9.

As shown in FIG. 9, the calculation processor 514 in this embodiment differs from the calculation processor 24 shown in FIG. 4 in that the path of data flow from an exclusive OR gate 518 through the shift registers S15, S14, S13 and S12, an exclusive OR gate 520, the shift registers S11, S10, . . . , S5, an exclusive OR gate 522, and the shift registers S4, . . . , S0, to a switch 524 is reversed. The remaining configuration of the calculation processor 514 may be similar to that of the calculation processor 24 shown in FIG. 4.

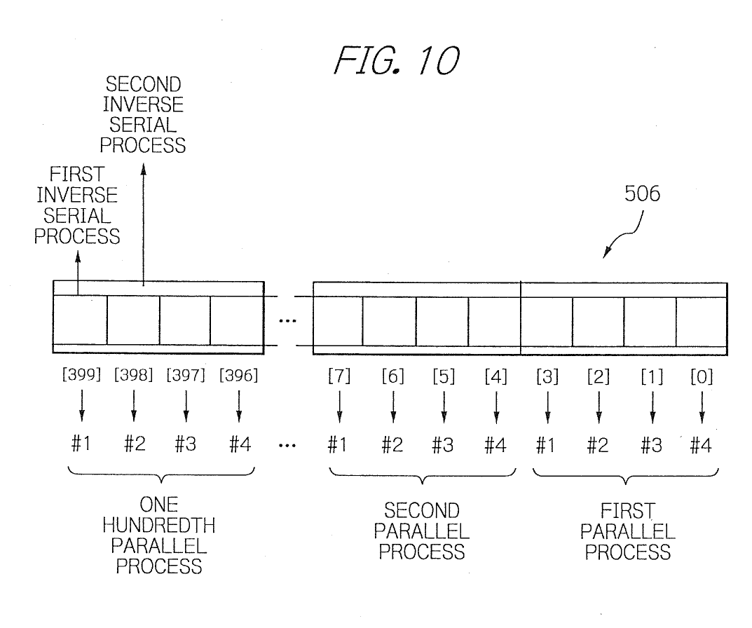

The calculation processor 514, while receiving the parallel enabling signal 502 for enabling from the calculation enable generator 504, performs 4-bit parallel calculation process based on 4-bit parallel data inputs provided from the input controller 500 as shown in FIG. 10. This is the same operation as the processing path of the parallel calculation shown in FIG. 6. In addition, the calculation processor 514, while receiving the inverse serial enabling signal 510 for enabling from the calculation enable generator 504, performs serial inverse calculations for data inputted on the input 512 in serial as shown in FIG. 10. This corresponds to a process such that data flow of the serial calculation process shown in FIG. 5 is reversed.

The calculation enable generator 504 receives the number of calculations generated according to the data length of a received data 506 on an input 530, a parallel calculation process start signal from its exterior on an input 532, and an inverse serial calculation process start signal on an input 534. The calculation enable generator 504, when receiving the parallel calculation process start signal 532 for enabling, outputs the parallel enabling signal 502 for enabling for a period of processing time corresponding to the number of calculations determined by its exterior. In addition, the calculation enable generator 504, when receiving the inverse serial calculation process start signal 534 for enabling from its exterior, outputs the inverse serial enabling signal 510 for enabling.

An operation of the CRC calculation circuit 50 in this embodiment will be described. In this embodiment, at the start time of the calculation, the number of times of 4-bit parallel calculation process is determined to be one hundred, and then the process is returned by two bits, i.e. the process corresponding to 398 bits in total, of which the illustrative operation will be described.

First, the shift registers in the calculation processor 514 are initialized. It is assumed that their initial values match a transmitter side. The calculation enable generator 504, when receiving the parallel calculation process start signal 532 from its exterior, turns on the parallel enabling signal 502 for enabling for a period of processing time corresponding to the determined number (one hundred) of the calculations.

The input controller 500, while receiving the parallel enabling signal 502 in its “ON” state, outputs the received data 506 four bits at a time to the output 508 in order from its LSB side.

The calculation processor 514, while receiving the parallel enabling signal 502 in its “ON” state, performs the parallel calculation process. The calculation enable generator 504, after finishing performing the processing cycle one hundred times, stops outputting the parallel enabling signal 502, thereafter, when receiving the inverse serial calculation process start signal 534 from its exterior, turning on the inverse serial enabling signal 510 for enabling for a period of processing cycle corresponding to the number (two) determined newly of the calculations.

The input controller 500, while receiving the inverse serial enabling signal 510 in its “ON” state, outputs data from the data in the MSB side, i.e. the final outputted data in serial in the already-outputted data to the output 512. The calculation processor 514, while receiving the inverse serial enabling signal 510 in its “ON” state, performs the inverse serial calculation process. The calculation enable generator 504, after finishing performing the processing cycle two times, stops outputting the inverse serial enabling signal 510.

The calculation processor 514 outputs remaining values held in the 16-bit shift register to the output 516. At this time, when the outputted values are not zero, the received data is determined to be wrong.

As described above, in the alternative embodiment, even when the number of bits for the calculation is not determined at the start time of the calculation, it can start with the provisionally-determined number of parallel calculations. Thereafter, when the number of bits for the calculation is fixed, the extra calculation is cancelled by the inverse serial calculation process, or the parallel calculations are further added to compensate for the excess or deficiency, whereby the number of bits to be calculated can be adjusted. Therefore, in this alternative embodiment, even when the number of bits for the calculation is not determined, the calculation process can be started.

Both illustrative embodiments are directed to the CRC calculation process for the received data, but the present invention is not to be restricted to such specific embodiments. For example, the present invention can also be applied to a CRC check code generator on a transmitter side. In addition, it can be applied to not only the CRC calculation but also, for example, a code generator using a shift register.

Furthermore, both illustrative embodiments are directed to the combination of a 4-bit parallel calculation process and a serial or inverse serial calculation process, but the parallel calculation process can be performed with not only four bits but also the other number of bits, and can also include the combination of plural parallel calculation processes. In addition, the parallel calculation process can be performed for even variable length data such that processed data for calculation include their data lengths, or received data represent data lengths.

The entire disclosure of Japanese patent application Nos. 2007-269944 and 2007-279513 filed on Oct. 17 and 26, 2007, respectively, including the specification, claims, accompanying drawings and abstract of the disclosure, is incorporated herein by reference in its entirety.

While the present invention has been described with reference to the particular illustrative embodiments, it is not to be restricted by the embodiments. It is to be appreciated that those skilled in the art can change or modify the embodiments without departing from the scope and spirit of the present invention.

What is claimed is:

1. A calculation processing device for calculating inputted data to output a result of calculation, comprising:
a parallel calculator for calculating the data in parallel;
a serial calculator for calculating the data in serial;
an input controller for converting the data to parallel and serial formats; and
a switching controller operative in response to processed data length of the data and a number of processes for enabling a calculation process of either one of said parallel and serial calculators to switch said parallel or serial calculator.

2. The device in accordance with claim 1, wherein said parallel and serial calculators process a CRC (Cyclic Redundancy Check) calculation for the data.

3. The device in accordance with claim 1, wherein a period of processing time depends on the data length of data to be calculated by said parallel and serial calculators.

4. The device in accordance with claim 1, wherein said input controller inversely outputs the converted data again, and said serial calculator performs an inverse serial process.
